(19) United States
(12) Patent Application Publication
(10) Pub. No.: US 2026/0231754 A1
(43) Pub. Date: Aug. 6, 2026

(54) COMPOSITE IC CHIPS WITH COMMON METALLIZATION LAYERS OVER MULTIPLE CHIPLETS

(71) Applicant: Intel Corporation, Santa Clara, CA (US)

(72) Inventors: Michael Langenbuch, Munich (DE); Thomas Wagner, Regelsbach (DE); Sidharthi Palanisamy, Taufkirchen (DE); Klaus Herold, Muenchen (DE); Carlton Hanna, San Jose, CA (US); Johannes Xaver Rauh, Kirchseeon (DE); Tim Helmut Krebs, Munich (DE); Richard Geiger, Muenchen (DE)

(73) Assignee: Intel Corporation, Santa Clara, CA (US)

(21) Appl. No.: 19/044,453

(22) Filed: Feb. 3, 2025

(51) Int. Cl. H01L 23/528; H01L 21/311; H01L 23/00; H01L 23/367; H01L 23/498; H01L 23/532; H01L 23/538; H01L 25/065; H05K 1/18

(52) U.S. Cl. CPC H10W 20/435; H10P 50/283; H10W 20/48; H10W 70/662; H10W 90/00; H05K 1/181; H10W 40/226; H10W 70/611; H10W 72/07232; H10W 74/10; H10W 90/401; H10W 90/724

(57) ABSTRACT

An IC device comprises a composite die structure that includes a base layer of comprising bulk silicon and a first chiplet integral with the base layer. The first chiplet includes first interconnects in first interconnect layers. A second chiplet is bonded to the base layer and horizontally adjacent to the first chiplet. The second chiplet includes second interconnects in second interconnect layers. A first dielectric material is between the first and second chiplets. Third interconnect layers extend over both the first and second interconnect layers. The third interconnect layers include third interconnects and a surface comprising conductive contacts opposite the base layer of the composite die structure. The third interconnects are coupled with the first interconnects, the second interconnects, and the conductive contacts. The third interconnect layers comprise a second dielectric material different from the first dielectric material.

### BACKGROUND

In electronics manufacturing, integrated circuit (IC) packaging is a stage of semiconductor device fabrication in which an IC that has been monolithically fabricated on a wafer and singulated into an IC chip is assembled into a “package” that can protect the IC chip from physical damage. The package can also communicatively connect the IC chip to other packaged IC chips and/or a scaled host component, such as a package substrate, or a printed circuit board (PCB).

In a disaggregated architecture, multiple IC chips can be assembled into a multi-chip package (MCP). Multi-chip packages may advantageously combine IC chips from heterogeneous silicon processes and/or combine small dis-aggregated chips from the same silicon process. For example, a CPU, GPU, IO chip, or high bandwidth memory (HBM) chips may be connected via an interposer. The interposer is typically connected to a package substrate which is mounted on a PCB with package balls. The interposer connects IC dies mounted on top of the interposer with each other and the package substrate. Some interposers include an embedded bridge device. However, there are many challenges with a disaggregated architecture in which multiple IC chips are integrated into a MCP unit using an interposer.

These MCP packaging techniques may suffer from latency and energy efficiency limitations. The signal path between IC chips in an MCP includes pads and solder bumps on each IC chip and metallization features (pads, traces, and vias) within the interposer. The pads, solder bumps, and metallization features introduce electrical resistances and signal losses not present in signal paths within an IC chip. Compared with signal paths within a monolithic IC chip, the signal path through an interposer between two IC chips is likely to be much longer, which increases electrical resistance. Pads and solder bumps, especially if bumps contain voids, tend to add resistance. Pads, solder bumps, and interposer metallization features may result in degradation of signal integrity and increased signal latency. In addition, compared with signal paths within an IC chip, larger signal driver circuitry may be are required to compensate for losses when an interposer is used in a disaggregated architecture. Further, the number of electrical connections possible in an MCP-interposer disaggregated architecture is limited as compared with the number of electrical connections that can be made within a monolithic IC chip.

### BRIEF DESCRIPTION OF THE DRAWINGS

The subject matter described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Views referred to as “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure. Further, where considered appropriate, reference labels have been repeated among the figures to indicate corresponding or analogous elements. In the figures:

FIGS. 1A and 1B illustrate a flow diagram of methods for forming an integrated circuit (IC) device package comprising a composite die structure including global interconnect layers over local interconnect layers of two or more chiplets, in accordance with some embodiments;

FIGS. 2A through 2K illustrate cross-sectional views of a workpiece evolving to include a composite die structure including global interconnect layers over local interconnect layers of two or more chiplets as selected operations in the methods illustrated in FIGS. 1A and 1B are performed, in accordance with some embodiments;

FIG. 3 illustrates a cross-sectional view of a workpiece evolving to include an IC device package comprising a composite die structure including global interconnect layers over local interconnect layers of two or more chiplets, as selected operations in the methods illustrated in FIGS. 1A and 1B are performed, in accordance with some embodiments.

FIG. 4 illustrates a cross-sectional view of a system that includes a plurality of IC device packages comprising multiple composite die structures integrated together with interposer attached to a host component, in accordance with some embodiments;

FIG. 5 illustrates a mobile computing platform and a data server machine employing one or more of the IC device packages illustrated in FIG. 2K and/or one or more of the IC device packages illustrated in FIG. 3, and/or the system illustrated in FIG. 4, in accordance with some embodiments; and

FIG. 6 is a functional block diagram of an electronic computing device employing one or more of IC device packages illustrated in FIG. 2K and/or one or more of the IC device packages illustrated in FIG. 3, and/or the system illustrated in FIG. 4, in accordance with some embodiments, in accordance with some embodiments.

### DETAILED DESCRIPTION

Embodiments are described with reference to the enclosed figures. While specific configurations and arrangements are depicted and discussed in detail, this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses all possible combinations of one or more of the associated listed items.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct physical contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the specific context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

Front-end-of-line (FEOL) semiconductor processing and structures refer to stages of IC fabrication where the individual devices (e.g., transistors, capacitors, resistors, etc.) are patterned in the semiconductor substrate or layer. FEOL generally covers everything up to (but not including) the deposition of metal interconnect layers. Following the last FEOL operation, the result is typically a wafer with isolated transistors (e.g., without any wires). FEOL fabrication stages may precede BEOL fabrication stages.

Back end of line (BEOL) semiconductor processing and structures refer stages of IC fabrication where the individual devices (e.g., transistors, capacitors, resistors, etc.) become interconnected with wiring on the wafer, e.g., the metallization or dielectric layers. BEOL includes contacts, insulating layers (dielectrics), metal levels, and bonding sites for chip-to-package connections. In the BEOL fabrication stages, contacts (pads), interconnect wires, vias and dielectric structures are formed. For modern IC processes, more than 10 metal layers may be added in the BEOL. BEOL processing generally has feature pitches much smaller than a feature pitch of interconnects that couple an IC chip to some host component (e.g., interposer or package substrate).

Embodiments described herein are directed to integrated circuit (IC) device packages comprising a composite die structure that includes global interconnect layers over local interconnect layers of two or more IC chiplets. IC device packages comprising a composite die structure provide a number of advantages over disaggregated architectures in which multiple IC chips are connected with an interposer. For example, the composite die structure may provide signal paths which have less electrical resistance than signal paths in an MCP-interposer disaggregated architecture. The signal paths between circuitry in different IC chiplets may be shorter and does not include pads and solder bumps at die-to-interposer interfaces. As a result, signal integrity and signal latency provided by the composite die structure may be better than what is provided in a comparable MCP-interposer design. A further advantage is that the composite die structure may provide significantly more and denser input/output (I/O) connections than is possible in MCP-interposer disaggregated architecture. In some examples, the signal density of IC device packages comprising a composite die structure may be 1,000,000 I/O/mm² or more. In comparison, the signal density of comparable monolithic IC chips connected with an interposer may be only about 1,000 I/O/mm². In addition to significantly more and denser I/O connections, the composite die structure may provide higher data transfer rates with less latency. Advantageously, the composite die structure may enable an interposer to be eliminated from some designs, thereby reducing part count and manufacturing steps.

IC devices that include a composite die structure are described herein. The composite die structure comprises a base layer of bulk silicon, two or more IC chiplets, and global interconnect layers. The composite die structure described herein may be manufactured with a hybrid of monolithic and die-level bonding techniques to form one or more of the features or attributes provided in accordance with various embodiments.

An “IC chiplet” or simply “chiplet” is a singulated die that has a smaller footprint than that of the base layer of bulk silicon of the composite die structure over which the chiplet is either fabricated on or bonded to. A chiplet may have a smaller footprint than that of the global interconnect layers. The fabricated chiplet(s) may be partially fabricated on the base layer in a monolithic manufacturing process associated with a host wafer. The bonded chiplet(s) may be partially fabricated in a monolithic process on a wafer different from the host wafer, singulated, and attached to the base layer. Fabrication of the partially fabricated chiplets is completed with formation of global interconnect layers over the chiplets. The bonded chiplet(s) may utilize the same or different semiconductor device technologies as the fabricated chiplet(s). As such, the composite die structures described herein may include chiplets from multiple different technology process nodes. Each chiplet may be fabricated using a combination of FEOL processing for device layers and BEOL processing for local interconnect layers. BEOL processing is used for the global interconnect layers. The device and local interconnect layers of each chiplet may be fabricated using FEOL and BEOL techniques for a particular technology process node.

Each chiplet includes a device layer and local interconnect layers over the device layer. The local interconnect layers of a chiplet comprise conductive interconnect features, i.e., metallization, separated by inter-level dielectric (ILD) material layers. A chiplet may have any suitable number of local interconnect layers. Each chiplet may have a same or different number of local interconnect layers. The technology process node of the chiplet may dictate a total number of (local and global) interconnect layers, which is a factor in determining the number of local interconnect layers in the chiplet. The number of local interconnect layers in a chiplet may be fewer than would be present if the chiplet were adapted for use in an MCP-interposer disaggregated architecture. In some examples, a chiplet may have three to six (3-6) conductive layers in its local interconnect layers.

The composite die structure includes a base layer of bulk silicon and a first IC chiplet integral with the base layer, i.e., the first IC chiplet is fabricated directly on the bulk silicon base layer. The composite die structure includes a second IC chiplet bonded to the base layer and horizontally adjacent to the first IC chiplet. The composite die structure may also include additional IC chiplets bonded to the base layer. The first chiplet includes first interconnects in its local (or first) interconnect layers and the second chiplet includes second interconnects in its local (or second) interconnect layers.

A global (or third) interconnect layers extend over both the first and second interconnect layers of the first and second chiplets. The global interconnect layers comprise third interconnects. The third interconnects in the global interconnect layers are coupled with the interconnects in the local interconnect layers of each chiplet. The third interconnects in the global interconnect layers are also coupled with conductive contacts at a surface of the composite die structure. The conductive contacts are at a surface opposite the base layer of the composite die structure. The global interconnect layers may comprise any suitable number of layers. In some examples, the global interconnect layers may have about three to eleven (3-11) conductive layers. With the trend to smaller nodes, the global interconnect layers may number as many 20 conductive layers. The first and second chiplets are horizontally adjacent, and a dielectric material is between the first and second chiplets in a gap or space between the chiplets.

Examples of composite, or heterogeneous, IC device structures including global interconnect layers over local interconnect layers of two or more chiplets are described below. The composite die structures include a monolithic base layer comprising bulk silicon, global interconnect layers, and two or more chiplets between the monolithic base layer and the global interconnect layers. A variety of fabrication methods may be practiced to form an IC device package having one or more of the features described herein.

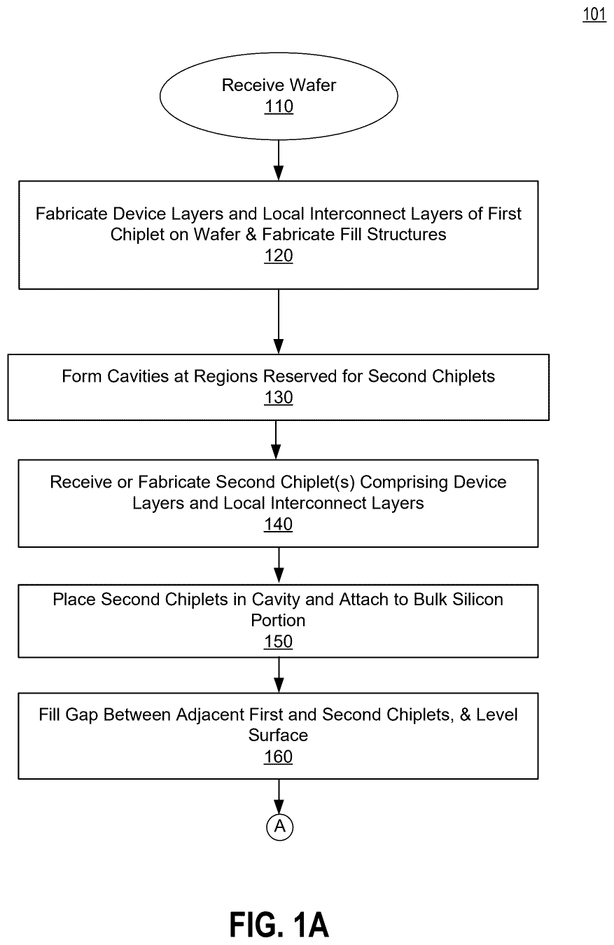

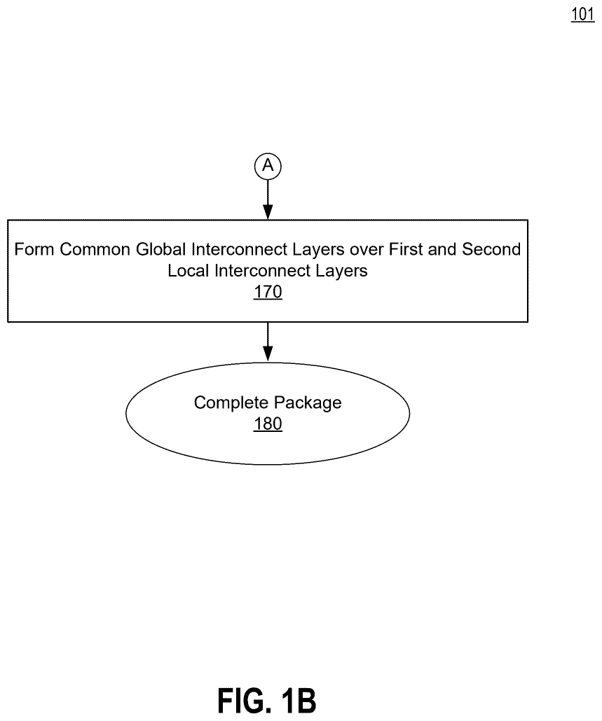

FIGS. 1A and 1B illustrate a flow diagram of methods for forming an IC device package comprising a composite die structure including global interconnect layers over local interconnect layers of two or more chiplets, in accordance with some embodiments. Methods 101 begin at input block 110 with the receipt of a wafer as a starting material

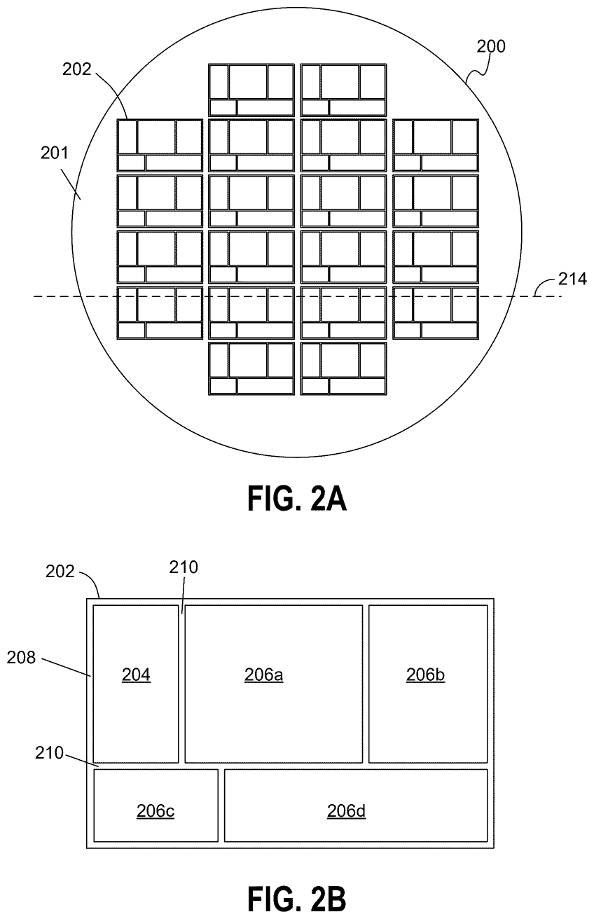

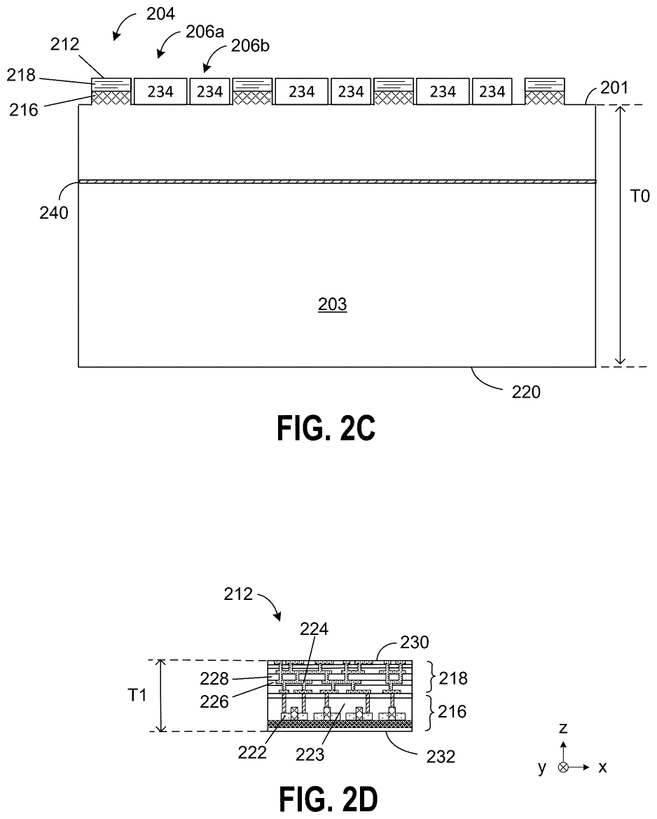

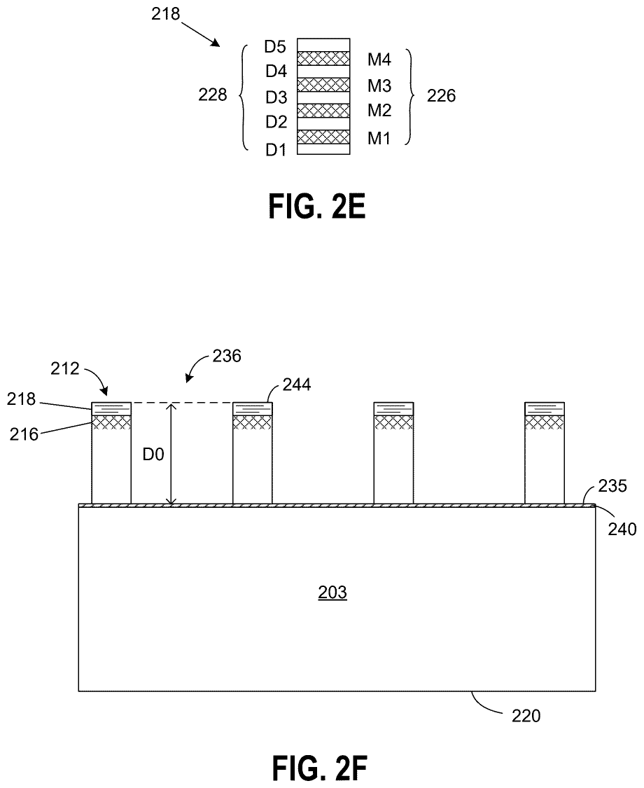

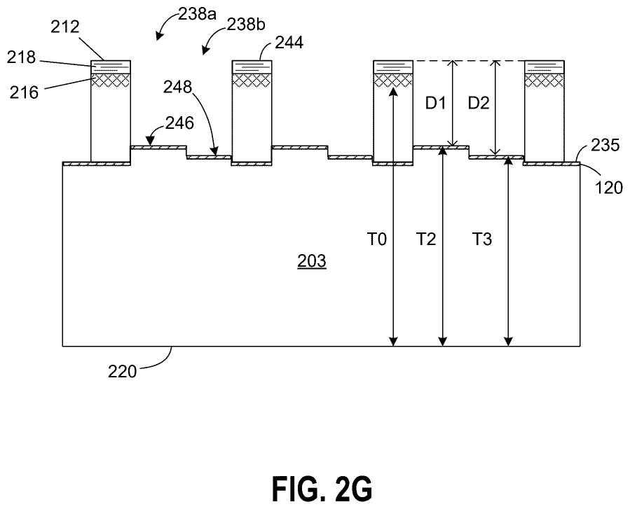

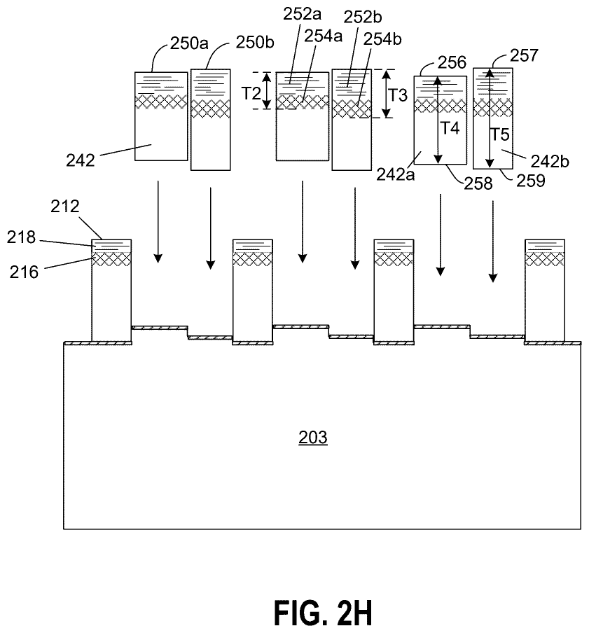

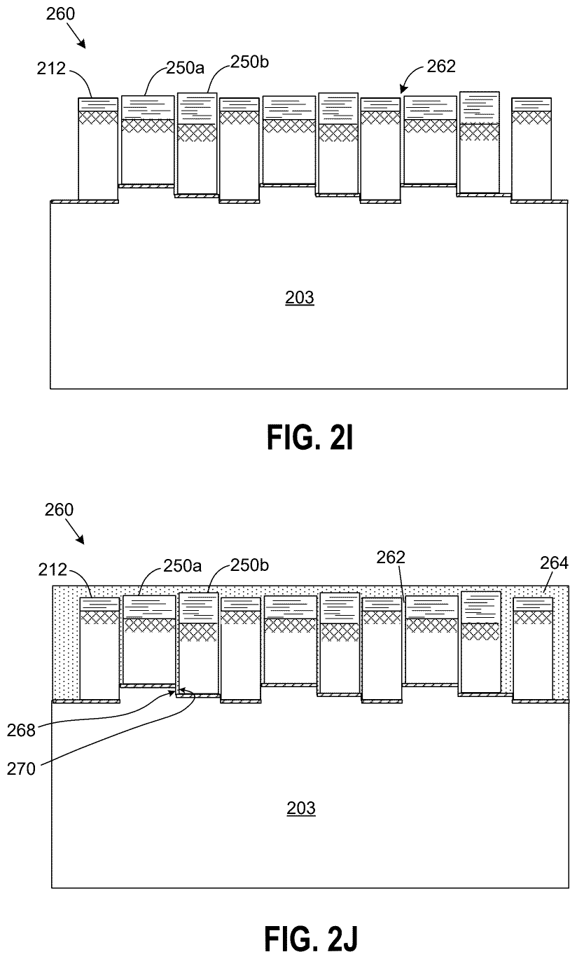

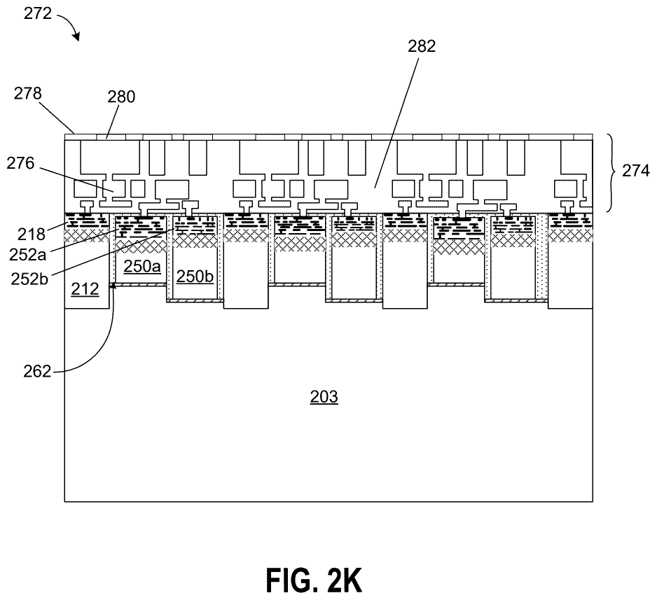

FIG. 2A is a plan view illustrating a wafer 200 that is at input block 110 in one example. Wafer 200 may have any composition and dimensions that are suitable for semiconductor manufacturing at any desired technology process node. In some examples, wafer may have a thickness of 500 microns and a diameter of 300 mm. For example, a composite die structure may include chiplets from multiple process nodes, e.g., 22 nm, 14 nm, 16 nm, 10 nm, 7 nm, 5 nm, and 2 nm. Wafer 200 may be suitable for the lowest or highest of those process nodes. As another example, wafer 200 may be suitable for the cheapest or most expensive of these process nodes. Other examples are contemplated; wafer 200 may be suitable for the process node of any of the chiplets in the composite die structure. In embodiments, wafer 200 comprises bulk silicon and includes multiple reticles 202. In the example illustrated in FIG. 2A, a highest technology node is 16 nm, which may be less expensive than other nodes. Wafer 200 is suitable for a first process node, e.g., the 16 nm process node. Wafer 200 may have a backside surface 220 opposite a topside surface 201.

FIG. 2B is a plan view illustrating one of the reticles 202, in accordance with some embodiments. Each reticle 202 includes one or more regions 204 reserved for fabricating a chiplet at the first process node and one or more regions 206, e.g., 206a, 206b, 206c, and 206d, for attaching chiplets monolithically fabricated on other wafers. The reticle 202 may have a kerf structure 208 required for a singulation process at an outside edge. Singulation is performed at later stage of manufacturing using any suitable technique, e.g., laser grooving, or plasma or blade dicing. Each of the regions 204 and 206 may be separated from the other regions by spacing streets 210.

Returning to FIG. 1, methods 101 continue at block 120 where a device layer and local interconnect layers of a first chiplet 212 are fabricated in region 204 on wafer 200. In addition, fill structures may be formed in regions reserved for attaching second chiplets at block 120. FIG. 2C is a cross-sectional view taken along line 214 illustrating a portion of wafer 200 after multiples instances of first chiplet 212 have been fabricated, in accordance with some embodiments. The portion of wafer 200 illustrated in FIG. 2C is referred to as substrate 203. In wafer form, substrate 203 may have any thickness TO extending between surfaces 201 and 220 sufficient for providing adequate mechanical support during monolithic fabrication of chiplet circuitry. In some exemplary embodiments, thickness TO is between 200 and 700 μm. Substrate 203 may be homogenous with a device layer 216 of a first chiplet 212.

The first chiplet 212 is “integral” (or “monolithic”) with the bulk silicon of wafer 200 in that it is fabricated directly on the bulk silicon using any suitable process known in the art. For example, surface 201 of the bulk silicon wafer 200 may be cleaned and polished, a layer of silicon dioxide may be grown on surface 201, photoresist may be applied and patterned using a photolithographic process to define a mask which is then used to etch features in the silicon dioxide using chemicals or plasma, impurities may be implanted in various features with a doping process, and metallization features may be formed to connect the features thereby forming devices, e.g., transistors, in a device layer 216. For example, the device layer 216 may comprise transistors fabricated at the first process node. Local interconnect layers 218 are formed directly on the device layer 216 using any suitable process known in the art. The local interconnect layers 218 may be formed using first process node technology. The chiplet 212 is not bonded to the bulk silicon using thermocompression bonding. Nor is chiplet 212 bonded to the bulk silicon using an adhesive.

In some embodiments, substrate 203 comprises an optional stop layer 240 buried in the substrate and which acts as a stop layer in a subsequent etch process. Stop layer 240 comprises any suitable material. In various embodiments, stop layer 240 comprises an oxide. In an example, stop layer 240 comprises SiO2. Stop layer 240 may be formed using any suitable process. In some embodiments, stop layer 240 may be formed using an ion implantation process. In other embodiments, stop layer 240 may be formed using a laser or other process. Any suitable ion or ions may be implanted. In one example, oxygen ions may be implanted to form a layer of silicon dioxide. In other examples, oxygen ions are implanted to form a layer of any suitable oxide. In a subsequent wet etch process, the implanted stop layer 240 will etch at a slower rate than the surrounding bulk silicon. In embodiments, stop layer 240 may have a thickness in the range of 10 nm to 100 nm.

FIG. 2D is an expanded cross-sectional view of chiplet 212. FIG. 2E is an expanded cross-sectional view of local interconnect layers 218 of chiplet 212. FIGS. 2D and 2E illustrate features of chiplet 212, which is fabricated at the first process node and is integral with the bulk silicon. FIGS. 2D and 2E may also be used to illustrate similar features of chiplets fabricated on other wafers that are singulated and attached to the bulk silicon, e.g., the attached chiplets 250 described below. For example, integral chiplet 212 comprise a device layer 216 and local interconnect layers 218. Similarly, the attached chiplets from other wafers comprise a device layer and local interconnect layers. Device layer 216 comprises devices, such as transistors 222 and device layer dielectric 223. The device layers of the attached chiplets 250 described below also comprise devices, such as transistors. Local interconnect layers 218 comprise conductive interconnect features 224, e.g., metallization, in conductive layers 226 separated by dielectric material layers 228 comprising inter-level dielectric (ILD) material. The local interconnect layers of the attached chiplets 250 described below also comprise interconnect features in conductive layers separated by ILD material layers. As illustrated, the local interconnect layers 218 are monolithically fabricated over device layer 216.

Referring to FIG. 2D, integral chiplet 212 has a vertical thickness T1 in the z-direction that is sufficient to house device layer 216 and local interconnect layers 218. Thickness T1 extends from top surface 230 of local interconnect layers 218 to bottom surface 232 of device layer 216. Similarly, the attached chiplets 250 described below have a thickness extending from a top surface of their local interconnect layers to bottom surface of their device layers. The thickness of a chiplet may depend on the process node, with some process nodes having thicknesses that are different from other process nodes. In an embodiment, a first chiplet 212 comprises a first thickness extending between a top surface of its first local interconnect layers to bottom surface of its first device layer, and a second chiplet 250 comprises a second thickness extending between a top surface of its second interconnect layers and a bottom surface of its second device layer, wherein the second thickness is different from the first thickness. In some examples, the thickness T1 of chiplet 212, and the attached chiplets 250 described below, have a thickness between about 100 nm and 1000 nm. In some examples, any of the chiplets 212 or 250 may have a thickness T1 that is less than 100 nm, e.g., 75 nm.

Device layer 216 may include any semiconductor material such as, but not limited to, predominantly silicon (e.g., substantially pure Si) material, predominantly germanium (e.g., substantially pure Ge) material, or a compound material comprising a Group IV majority constituent (e.g., SiGe alloys, GeSn alloys). In other embodiments, the semiconductor material is a Group III-V material comprising a Group III majority constituent and a Group IV majority constituent (e.g., InGaAs, GaAs, GaSb, InGaSb). Device layer 216 may have a thickness of 100-300 nm, for example. Device layer 216 need not be a continuous layer of semiconductor material, but rather may include active regions of semiconductor material surrounded by field regions of device layer dielectric 223 (isolation dielectric). During FEOL processing, active and/or passive devices are fabricated in chiplet device layer 216. Additionally, or in the alternative, chiplet device layer 216 may include active devices other than FETs. For example, the device layer 216 of a chiplet may include electronic memory structures, such as magnetic tunnel junctions (MTJs), or the like. In addition to active devices, or instead of active devices, device layer 216 may include passive devices (e.g., resistors, capacitors, inductors, etc.).

The active and/or passive devices are fabricated in chiplet device layer 216 at some device size, density, materials, or architecture associated with a particular technology process node. The term “technology process node,” “process node,” or the like refer to a specific semiconductor manufacturing process and its design rules. Historically, the name referred to dimensions of particular transistor features of semiconductors manufactured by all foundries. However, process node no longer necessarily specifies dimensions of the same features that were specified in the past. Rather, recent technology nodes such as 22 nm, 16 nm, 14 nm, and 10 nm simply refer to a specific generation of chips made using a particular technology. In addition, the technical specifications today for a particular node differ among different foundries. For example, the 10 nm node of one foundry may be comparable with the 7 nm of another foundry. For this reason, while the integral chiplet 212 and the attached chiplets 250 described below may be fabricated at any known process node by any foundry, the chiplets may distinguished from one another by particular features.

In some embodiments, the active devices are field effect transistors (FETs), which may have the feature dimensions presented in Tables 1 and 2 below, or other feature dimensions. The FETs in a device layer may be of any architecture (e.g., planar, non-planar, single-gate, multi-gate). In some embodiments, a first chiplet comprises first device layers comprising first transistors 222 comprising a single gate, and the second chiplet comprises second device layers comprising second transistors comprising two or more gates. In some embodiments, a chiplet comprises FETs having a gate-all—around or ribbon architecture.

Examples of some the features in the device layer 216 of integral chiplet 212 and device layers of the attached chiplets 250 described herein are presented in Tables 1 and 2. The example features presented are not intended to be comprehensive and do not disclose all possible features that may be in a device layer or their dimensions.

TABLE 1

| Process Node | Fin Pitch (nm) | Fin Width (nm) | Fin Height (nm) |
|---|---|---|---|
| 22 nm | 60 | 8 | 34 |
| 16 nm | 48 | — | 37 |
| 14 nm | 42 | 8 | 42 |
| 10 nm | 34 | 7 | 53 |
| 7 nm | 30 | 6 | 52 |

Table 2 present some example specifications for length of gate (Lg), contacted gate pitch (CPP), and minimum metal pitch (MMP) features in a device layer.

TABLE 2

| Process Node | L_{g} (nm) | CCP (nm) | MMP (nm) |
|---|---|---|---|
| 22 nm | 26 | 90 | 80 |
| 16 nm | 34 | 90 | 64 |
| 14 nm | 20 | 70 | 52 |
| 10 nm | — | 54 | 36 |
| 7 nm | — | 57 or 64 | 40 |
| 5 nm | | 51 | 30 |
| 3 nm | | 48 | 24 |
| 2 nm | | 45 | 20 |

In some embodiments, a first chiplet comprises first device layers comprising a first feature, a second chiplet comprises second device layers comprising the same first feature, wherein the first feature of the first device layers comprises a first dimension, and the first feature of the second device layers comprises a second dimension different from the first dimension. For example, the first feature may be any one of fin pitch, width, or height, or Lg, CPP, or MMP. The second chiplet comprises second device layers comprising the same first feature, e.g., fin pitch, width, or height, or Lg, CPP, or MMP. Continuing the example, assume the first feature is the CCP. The first feature of the first device layer of a first chiplet may be a CCP having a dimension of 90 nm, and the first feature of the second device layer of a second chiplet may be a CCP having a dimension of 51 nm.

FIG. 2E is an expanded cross-sectional view of one example of local interconnect layers 218 of a chiplet, e.g., integral chiplet 212 or any of the attached chiplets 250 described below. The illustrated example includes four conductive layers 226 (M1, M2, M3 and M4) separated by five dielectric material layers 228 (D1, D2, D3, D4, and D5). Conductive layer M1 is coupled with the device layer. In some examples, D1 is omitted and M1 is on the device layer. Each conductive layer 226 has a thickness and conductive interconnect features 224 in a layer have a minimum width and pitch. While conductive layers 226 and dielectric material layers 228 are shown as having similar thicknesses, this is to simplify the illustration. Layer thicknesses for both conductive layers 226 and dielectric material layers 228 may range from 10 nm in the lower metallization layers near the interface with device layer 216, to 5 μm or more, in the upper metallization layers. In various embodiments, each conductive layer 226 has thickness between 10 nm and 120 nm. Typical thicknesses are, for example, 30 nm, 60 nm, or 80 nm. In some embodiments, a conductive layer may have thickness 490 nm or less. Conductive layers 226 may comprise any composition known to be suitable for monolithic integrated circuitry, such as, but not limited to, Cu, Ru, W, Ti, Ta, Co, their alloys, or nitrides.

In some embodiments, ILD materials between conductive layers 226 vary in composition with lower dielectric material layers 228, e.g., D1, D2, comprising a low-k dielectric material and uppermost dielectric material layers 228, e.g., D4, D5, comprising a conventional dielectric material (e.g., having a dielectric constant of approximately 3.5, or more). Confining low-k dielectric materials from a bond interface in this manner may advantageously improve bond strength and/or quality. In other embodiments where low-k dielectric material is able to form a strong bond interface, all dielectric material layers 228 may be a low-k material (e.g., having a relative permittivity of 1.5-3.0). Dielectric material layers 228 may be of any material composition known to be suitable as an insulator of monolithic integrated circuitry, such as, but not limited to, silicon dioxide, silicon nitride, silicon oxynitride, or a low-k material having a relative permittivity below 3.5. In embodiments, dielectric material layers 228 comprise an inorganic composition.

As mentioned, block 120 of methods 101 includes fabricating fill structures in regions 206, e.g., 206a, 206b, 206c, and 206d, reserved for attaching chiplets previously monolithically fabricated on other wafers. The example illustrated in FIG. 2C shows substrate 203 after multiples instances of fill structures 234 have been fabricated in regions 206b, 206c adjacent to first chiplet 212, in accordance with some embodiments. Fill structures 234 may include dummy features, e.g., dummy metallization and dielectric features. Some package architectures require one or more dummy fill structures for mechanical stabilization, thermals reason, or both.

Returning to FIG. 1, block 130 of methods 101 include formation of cavities in regions 206, e.g., 206a, 206b, 206c, and 206d, that are reserved for attaching chiplets previously monolithically fabricated on other wafers. Block 130 includes removing fill structures 234 in the reserved regions and may include removing material from substrate 203. FIG. 2F illustrates substrate 203 after cavities 236 have been formed in regions 206 reserved for attaching second chiplets monolithically fabricated on other wafers. The second chiplets monolithically fabricated on other wafers may include a handle 242 comprised of, e.g., bulk silicon, and cavities 236 are formed at a depth DO necessary to accommodate the thickness of handle 242. Formation of cavities 236 results in the creation of a surface 235 at the bottom of the cavity, which is opposite surface 220. Depth DO extends between surface 235 and surface 244 of first chiplet 212. The surface 244 is at a top layer of local interconnect layers 218 opposite a bottom layer of local interconnect layers 218 on device layer 216. In various embodiments, cavity depth can be any suitable depth, such as, 20 μm, 100 μm, or up to ninety percent (90%) of the thickness of the 16 nm wafer. The cavities 236 may be formed using any suitable process, e.g., various etch processes or laser ablation. If a wet etch process is used, the depth of cavity 236 may be determined by a time the process is run or by optional stop layer 240. In the case of laser ablation, the depth of cavity 236 may be determined by controlling the number, duration, and/or power of laser pulses, or by the optional stop layer 240.

In some embodiments, the depth of formed cavities reserved for attaching second chiplets monolithically fabricated on other wafers may vary by region. FIG. 2G illustrates substrate 203 after cavities 238a and 238b of different depths have been formed in regions 206b and 206c. A second chiplet may have electrical, thermo-mechanical, or other requirements that differ from the first chiplet or from other types of second chiplets. To accommodate the various requirements of second chiplets, a dedicated cavity depth may be provided, e.g., cavity 238a has a depth of D1 and cavity 238b has a depth of D2. Formation of cavity 238a results in the creation of a surface 246 at the bottom of cavity 238a and opposite surface 220. Formation of cavity 238b results in the creation of a surface 248 at the bottom of cavity 238b and opposite surface 220. Depth D1 extends between surface 246 and surface 244 of first chiplet 212. Depth D2 extends between surface 248 and surface 244 of first chiplet 212. Formation of cavity 238a also results in the creation of a thickness T2 of substrate 203 between surface 246 and backside surface 220. In addition, formation of cavity 238b results in the creation of a thickness T3 of substrate 203 between surface 248 and backside surface 220.

Returning to FIG. 1, block 140 of methods 101 includes receiving one or more second chiplets previously monolithically fabricated on wafers other than wafer 200. In some embodiments, block 140 comprises fabricating the second chiplets on other wafers. FIG. 2H illustrates second chiplets prior to attaching the chiplets to substrate 203, in accordance with some embodiments.

The second chiplet(s) 250 may be partially or fully fabricated in a monolithic process separate from that of first chiplet 212. As such, the second chiplet(s) 250 may utilize the same or different semiconductor device technologies as that of first chiplet 212. In one example, a composite die structure may include the first chiplet 212 from a first technology process node, a second chiplet 250a from a second technology process node, and a third chiplet 250b from a third technology process node.

Each second chiplet(s) 250 comprises local interconnect layers 252 formed directly on a device layer 254. The number of local interconnect layers 252 can vary among the first chiplet 212 and second chiplet(s) 250. For example, a second chiplet 250a may have local interconnect layers 252 comprising five conductive layers separated by dielectric material layers, a second chiplet 250b may have local interconnect layers 252 comprising six conductive layers separated by dielectric material layers, and a first chiplet may have local interconnect layers 218 comprising four conductive layers separated by dielectric material layers.

The device layer 254 of chiplets 250 may include any of the devices, including any of the types of transistors described above with reference to chiplet 212. The device layer 254 of chiplets 250 may include any semiconductor material described above with reference to chiplet 212. The transistors in device layer 254 of chiplets 250 may include any feature and dimension presented in Tables 1 and 2.

The local interconnect layers 252 of chiplets 250 may include interconnect features in conductive layers separated by ILD material layers. Layer thicknesses for both conductive layers and dielectric material layers of chiplets 250 may be in the same ranges as described above for chiplet 212. In various embodiments, each conductive layer of chiplets 250 has thickness between 10 nm and 120 nm. In some embodiments, a conductive layer may have thickness 490 nm or less. Conductive layers may have any of the compositions described above for chiplet 212. ILD materials of chiplets 250 may be the same or similar to the ILD materials of chiplets 212. ILD materials of chiplets 250 may vary in composition with lower dielectric material layers 228, e.g., D1, D2, comprising a low-k dielectric material and uppermost dielectric material layers 228, e.g., D4, D5, comprising a conventional dielectric material (e.g., having a dielectric constant of approximately 3.5, or more). The dielectric material layers of chiplets 250 may be of any material composition known to be suitable as an insulator of monolithic integrated circuitry, such as, but not limited to, silicon dioxide, silicon nitride, silicon oxynitride, or a low-k material having a relative permittivity below 3.5. In embodiments, the dielectric material layers of chiplets 250 comprise an inorganic composition.

In an embodiment, a chiplet 250a comprises a first thickness T2 extending between a top surface 256 of its local interconnect layers 252a to bottom surface of its device layer 254a, and chiplet 250b comprises a second thickness T3 extending between a top surface 257 of its interconnect layers 252b and a bottom surface of its device layer 254b, wherein the second thickness T3 is different from the first thickness T2.

In an embodiment, a chiplet 250a comprises a first thickness T4 extending between a top surface 256 of its local interconnect layers 252a and a bottom surface 258 of its handle 242a, and chiplet 250b comprises a second thickness T5 extending between a top surface 257 of its local interconnect layers 252b and a bottom surface 259 of its handle 242b, wherein the second T5 is different from the first thickness T4.

Functionally, first chiplet 212 and second chiplet(s) 250a, 250b may, for example, be any of a wireless radio circuit, microprocessor circuit, electronic memory circuit, floating point gate array (FPGA), power management and/or power supply circuitry, or include a MEMS device. In some other examples, first chiplet 212 and second chiplet(s) 250 may include banks of active repeater circuitry to improve host IC interconnects (e.g., network-on-chip architectures). In other examples, first chiplet 212 and second chiplet(s) 250 may include clock generator circuitry or temperature sensing circuitry. In other examples, first chiplet 212 and second chiplet(s) 250 may include one or more electrostatic discharge (ESD) protection circuitry banks in-line with first-level interconnects of the composite chip structure. In still other examples, the first chiplet 212 and second chiplet(s) 250 may include a second level of logic circuitry that implements 3D circuitry (e.g., mesh network-on-chip architectures).

Returning to FIG. 1, block 150 of methods 101 includes attaching the second chiplets 250 to substrate 203. FIG. 2I illustrates a workpiece 260 comprising second chiplets 250 after attachment to substrate 203, in accordance with some embodiments. The second chiplets can be individually tested and only known good chiplets are attached to the substrate 203. The chiplets 250 may be singulated from a wafer and placed within a reserved cavity using in suitable method, e.g., a pick-and-place tool. In some embodiments, chiplets 250 may be placed within cavities in a wafer-to-wafer operation. Chiplets 250 may have lateral dimensions slightly smaller than the reserved cavity. After chiplet placement, a lateral gap 262 may is present between adjacent chiplets. In some embodiments, the gap 262 may be 0.5 μm to 5.0 μm. The second chiplets may be attached using any suitable technique, such as thermocompression bonding. The chiplet attachment process may include grinding the backside surface of the mono reticle wafer on which the second chiplet was fabricated and forming an oxide layer on the backside surface. In some examples, the bottom surface of a cavity, e.g., surface 235, may be grinded or subjected to other surface treatment.

Returning to FIG. 1, block 160 of methods 101 includes filling gaps between adjacent chiplets with a dielectric material and leveling the surface of the workpiece. FIG. 2J illustrates the workpiece 260 after application of a dielectric material 264 and surface planarization, in accordance with some embodiments. Dielectric material 264 may be applied using a spin-on, or other suitable method. The dielectric material 264 may be provide within a gap 262 between the chiplet 212 and an adjacent chiplet 250, as well as within a gap 262 between chiplets 250a and 250b. Due to a difference in cavity depth, e.g., D1 is different from D2, substrate 203 may have a sidewall 268. In an embodiment, dielectric material 264 is between sidewall 268 of substrate 203 and sidewall 270 of a chiplet, e.g., chiplet 250b.

The dielectric material 264 may be a front-end dielectric, such as silicon dioxide (SiO2) and other high-k dielectrics. In embodiments, dielectric material 264 may be a polymer or an inorganic composition. In embodiments, dielectric material 264 may comprise a composition that is different from a composition of an ILD material within the local interconnect layers of either chiplet 212 or any of chiplets 250. As one example, dielectric material 264 may comprise a composition that is different from a composition of dielectric material layers 228. In embodiments, dielectric material 264 may comprise a first relative dielectric permittivity, and a dielectric material within the local interconnect layers of either chiplet 212 or any of chiplets 250 comprises a second relative dielectric permittivity that is lower than the first relative dielectric permittivity of dielectric material 264.

After attachment of second chiplets 250 to substrate 203, there may be slight height differences, e.g., less than about 1 micron, between the chiplets. Operations at block 160 may also include leveling the surface of the workpiece after applying dielectric material 264 using any suitable process, e.g., CMP.

Returning to FIG. 1, block 170 of methods 101 includes forming common global interconnect layers over the local interconnect layers of two or more chiplets. FIG. 2K illustrates workpiece 260 evolving into a composite die structure 272 comprising global interconnect layers over local interconnect layers of first and second chiplets, in accordance with some embodiments.

As illustrated, global interconnect layers, e.g., third interconnect layers 274, extend over all of the local interconnect layers 218, 252a, and 252b of chiplets 212, 250a, and 250b. The third interconnect layers 274 comprise third interconnect features 276, and a surface 278 comprising FLI interfaces 280 (also referred to herein as conductive contacts) opposite a base layer, e.g., substrate 203, of the composite die structure 272. The third interconnect features 274 are coupled with the interconnects in local interconnect layers 218, local interconnect layers 252a, and local interconnect layers 252b. The third interconnect features 274 couple the interconnects in the local interconnect layers with FLI interfaces 280.

The third interconnect features 276 in the third interconnect layers 274 are in conductive layers. Like the local interconnect layers, these conductive layers are separated by dielectric material layers comprising ILD material. The global interconnect layers, e.g., third interconnect layers 274, may comprise any suitable number of conductive and dielectric layers. In some examples, the global interconnect layers may have about three to eleven (3-11) conductive layers. The global interconnect layers are monolithically fabricated over the local interconnect layers.

Each conductive layer of the third interconnect layers 274 has a thickness and the third interconnect features 276 in a layer have a minimum width and pitch. Layer thicknesses for both conductive layers and dielectric material layers of the third interconnect layers 274 may range from 500 nm in the lower metallization layers near the interface with the local interconnect layers to 5 μm, or more, in the upper metallization layers near surface 278. In various embodiments, each conductive layer has thickness between 500 nm and 10 μm.

In an embodiment, conductive layers of the local interconnect layers 218 of integral chiplet 212 or any of the attached chiplets 250 have a maximum thickness of 500 nm or less and conductive layers of the third interconnect layers 274 a minimum thickness of 500 nm. In another embodiment, conductive layers of the local interconnect layers 218 of integral chiplet 212 or any of the attached chiplets 250 have a maximum thickness of 500 nm or less and conductive layers of the third interconnect layers 274 a minimum thickness equal to the maximum thickness of the conductive layers of the local interconnect layers 218.

Conductive layers of the third interconnect layers 274 may have any composition known to be suitable for monolithic integrated circuitry, such as, but not limited to, Cu, Ru, W, Ti, Ta, Co, their alloys, or nitrides. Dielectric material layers of the third interconnect layers 274 may comprise a dielectric material 282. Dielectric material 282 may be a conventional dielectric material (e.g., having a dielectric constant of approximately 3.5, or more). Dielectric material 282 may be of any material composition known to be suitable as an insulator of monolithic integrated circuitry, such as, but not limited to, silicon dioxide, silicon nitride, silicon oxynitride. In embodiments, the dielectric material 282 comprises an inorganic composition. In embodiments, the dielectric material 282 of one or more of the dielectric material layers of the third interconnect layers 274 comprises an organic composition. For example, the dielectric material 282 in an upper dielectric layer proximate surface 278 may comprise an organic composition.

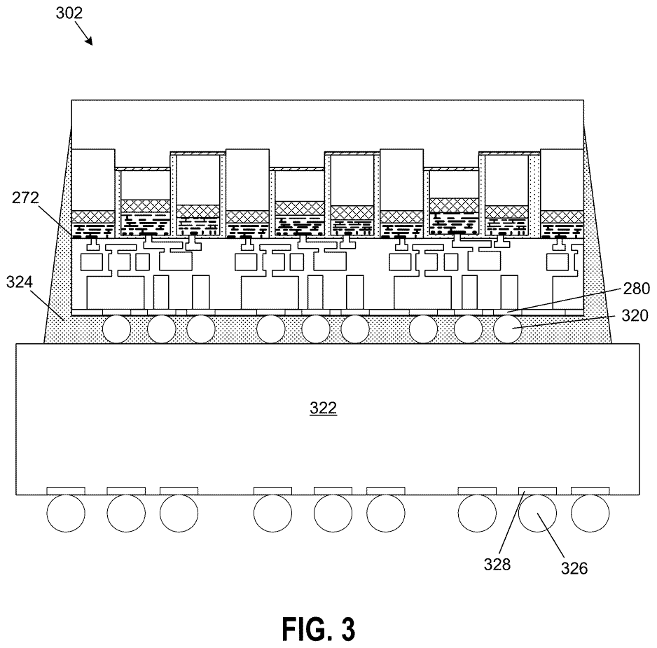

Returning to FIG. 1, block 180 of methods 101 where fabrication of an IC device package comprising a composite die structure is completed. Operations at block 180 include thinning, singulating, and attaching a composite die structure to a host component. FIG. 3 illustrates a cross-sectional view of an IC device package 302 comprising a composite die structure 272, in accordance with some embodiments. As illustrated, the composite die structure 272 is attached to a host component 322 by solder first level interconnects (FLI) features 320. The host component 322 may be any interposer or package substrate, for example.

Solder FLI features 320 are in contact with FLI interfaces 280, and may be in contact with any suitable host-side FLI interface (not depicted). Solder FLI features 320 may be of any composition (e.g., SAC) and applied by any technique. Non-solder embodiments are also possible where FLI interfaces 280 are directly bonded (e.g., Cu—Cu bumps) to host component 322. In some embodiments, host component 322 is predominantly silicon. Other materials known to be suitable as interposers or package substrates may also be employed as host component 322 (e.g., an epoxy preform, etc.). Host component 322 may include one or more metallized redistribution levels (not depicted) embedded within a dielectric material. Host component 322 may also include one or more chiplets embedded therein. For example, a chiplet (not depicted) may be embedded within the metallized redistribution levels of host component 322. Host component 322 may include second level interconnects (SLI) 326 that are in contact with SLI interfaces 328. SLI 326 may comprise any solder (ball, bump, etc.) suitable for a given host board architecture (e.g., surface mount FR4, etc.).

In addition, IC device package 302 may include a mold material 324 to encapsulate the composite die structure 272. In some examples, IC device package 302 may include an underfill material (not shown) on surface 278 of composite die structure 272 and on a surface of host component 322 facing surface 278. The mold material 324 and underfill material may comprise any material known in the art, such as organic materials and fillers.

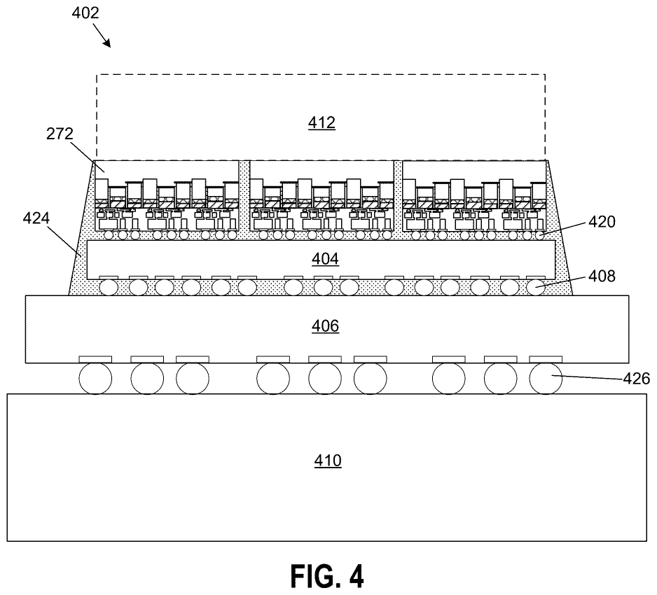

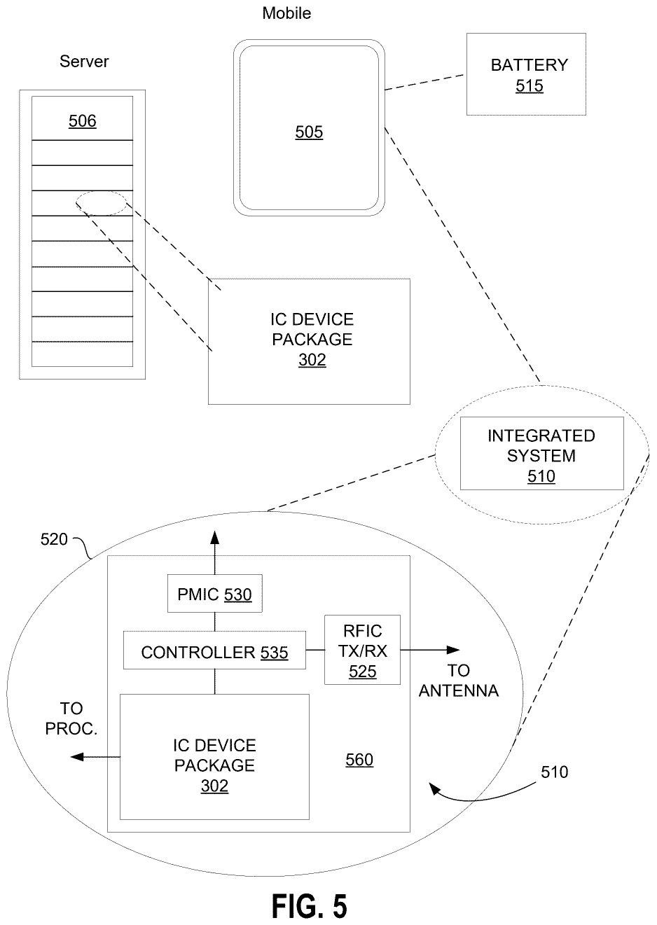

FIG. 4 illustrates an exemplary microelectronic system 402 that includes a plurality of composite die structures 272 integrated together with an interposer 404 and a host component 406. As shown, composite die structures 272 are coupled to interposer 404 by FLI features 420. The interposer 404 may be passive component including only metallization for routing signals or an active component including devices, such as transistors, inductors, capacitors, and resistors. The interposer 404 is coupled with host component 406 (e.g., a package substrate) by interconnects 408. The host component 406 is further coupled to a host board 410 by SLI features 426. Host board 410 may be a printed circuit board (PCB).

Host component 406 may include one or more metallized redistribution levels (not depicted) embedded within a dielectric material. Host component 406 may also include one or more IC die embedded therein. Also illustrated in dashed line, one or more heat spreaders and/or heat sinks 412 may be further coupled to system 402, which may be advantageous, for example, where composite die structures 272 comprises one or more CPU cores or other circuitry of similar power density. System 402 may include a mold material 424 to encapsulate the multiple composite die structures 272. In some examples, system 402 may include an underfill material (not shown) between facing surfaces of the composite die structures and the interposer, and between facing surfaces of the interposer and the host component. The mold material 424 and underfill material may comprise any material known in the art, such as organic materials and fillers.

FIG. 5 illustrates a mobile computing platform and a data server machine employing an IC device comprising a composite die structure including global interconnect layers over local interconnect layers of two or more chiplets, for example as described elsewhere herein. Server machine 506 may be any commercial server, for example including any number of high-performance computing platforms disposed within a rack and networked together for electronic data processing, which in the exemplary embodiment includes an IC device package 302 comprising a composite die structure 272, for example as described elsewhere herein. The mobile computing platform 505 may be any portable device configured for each of electronic data display, electronic data processing, wireless electronic data transmission, or the like. For example, the mobile computing platform 505 may be any of a tablet, a smart phone, laptop computer, etc., and may include a display screen (e.g., a capacitive, inductive, resistive, or optical touchscreen), a chip-level or package-level integrated system 510, and a battery 515.

Whether disposed within the integrated system 510 illustrated in the expanded view 520, or as a stand-alone package within the server machine 506, the integrated system or server machine includes an IC device package 302 comprising a composite die structure 272, for example as described elsewhere herein. IC device package 302, as described elsewhere herein, may be further coupled to a host substrate 560, along with, one or more of a power management integrated circuit (PMIC) 530, RF (wireless) integrated circuit (RFIC) 525 including a wideband RF (wireless) transmitter and/or receiver (TX/RX) (e.g., including a digital baseband and an analog front-end module further comprises a power amplifier on a transmit path and a low noise amplifier on a receive path), and a controller 535. PMIC 530 may perform battery power regulation, DC-to-DC conversion, etc., and so has an input coupled to battery 515 and with an output providing a current supply to other functional modules. As further illustrated, in the exemplary embodiment, RFIC 525 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 4G, and beyond.

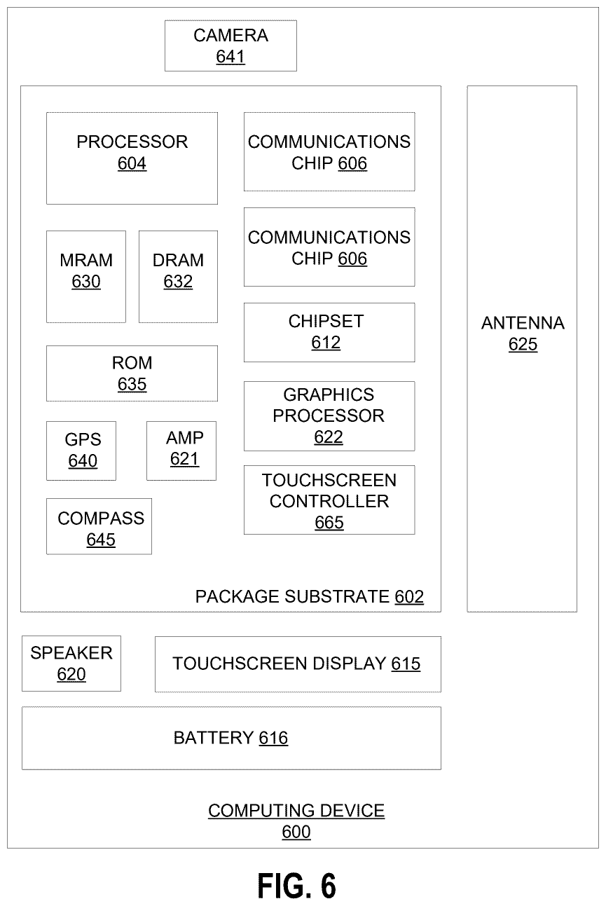

FIG. 6 is a functional block diagram of an electronic computing device 600, in accordance with an embodiment of the present invention. The computing device may include any of the devices or structures discussed elsewhere herein, e.g., an IC device package 302 comprising a composite die structure 272. Device 600 further includes a package substrate 602 hosting a number of components, such as, but not limited to, a processor 604 (e.g., an applications processor). Processor 604 may be physically and/or electrically coupled to package substrate 602. In some examples, processor 604 is within an IC device package 302 comprising a composite die structure 272, for example, as described elsewhere herein. Processor 604 may be implemented with circuitry in either or both of a host IC chip and a chiplet. In general, the term “processor” or “microprocessor” may refer to any device or portion of a device that processes electronic data from registers and/or memory to transform that electronic data into other electronic data that may be further stored in registers and/or memory.

In various examples, one or more communication chips 606 may also be physically and/or electrically coupled to the package substrate 602. In further implementations, communication chips 606 may be part of processor 604. Depending on its applications, computing device 600 may include other components that may or may not be physically and electrically coupled to package substrate 602. These other components include, but are not limited to, volatile memory (e.g., DRAM 632), non-volatile memory (e.g., ROM 635), flash memory (e.g., NAND or NOR), magnetic memory (MRAM 630), a graphics processor 622, a digital signal processor, a crypto processor, a chipset 612, an antenna 625, touchscreen display 615, touchscreen controller 665, battery 616, audio codec, video codec, power amplifier 621, global positioning system (GPS) device 640, compass 645, accelerometer, gyroscope, speaker 620, camera 641, and mass storage device (such as hard disk drive, solid-state drive (SSD), compact disk (CD), digital versatile disk (DVD), and so forth), or the like. In some exemplary embodiments, one or more of the functional blocks noted above are within an IC device comprising a composite die structure, described elsewhere herein. For example, processor 604 may be implemented within circuitry of one or more chiplets of an IC device comprising a composite die structure, and an electronic memory (e.g., MRAM 630 or DRAM 632) may be implemented with circuitry of one or more chiplets of the IC device comprising a composite die structure.

Communication chips 606 may enable wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chip 606 may implement any of a number of wireless standards or protocols. As discussed, computing device 600 may include a plurality of communication chips 606. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

Example 1: An integrated circuit (IC) device, comprising: a base layer of a composite die structure comprising bulk silicon and a first chiplet integral with the base layer, the first chiplet comprising first interconnects in first interconnect layers; a second chiplet bonded to the base layer and horizontally adjacent to the first chiplet, the second chiplet comprising second interconnects in second interconnect layers; a dielectric material between the first and second chiplets; and third interconnect layers extending over both the first and second interconnect layers, the third interconnect layers comprising third interconnects, and a surface comprising conductive contacts opposite the base layer of the composite die structure, wherein the third interconnects are coupled with the first interconnects, the second interconnects, and the conductive contacts.

Example 2: The IC device of example 1, wherein: the dielectric material is a first dielectric material; the first interconnect layers comprise a plurality of inter-layer dielectric (ILD) material layers; the first chiplet comprises a device layer under the first interconnect layers; and a layer of the ILD material layers proximate the device layer comprises a second dielectric material different from the first dielectric material.

Example 3: The IC device of example 2, wherein the first dielectric material comprises a first relative dielectric permittivity, and the second dielectric material comprises a second relative dielectric permittivity lower than the first relative dielectric permittivity.

Example 4: The IC device of example 1, wherein the dielectric material is a first dielectric material, and the third interconnect layers comprise a second dielectric material different from the first dielectric material.

Example 5: The IC device of example 4, wherein: the first dielectric material comprises an inorganic material; and the second dielectric material comprises an organic material.

Example 6: The IC device of any of examples 1 through 5, further comprising a stop layer vertically between the second chiplet and the base layer.

Example 7: The IC device of any of examples 1 through 6, wherein: the first chiplet comprises a first thickness extending between the third interconnect layers and a lowest level of a first device layer under the first interconnect layers; and the second chiplet comprises a second thickness extending between the third interconnect layers and the base layer, wherein the second thickness is different from the first thickness.

Example 8: The IC device of any of examples 1 through 7, wherein: the base layer further comprises: a first surface, a second surface, and a third surface, wherein the second and third surfaces are both opposite the first surface, and the second surface is non-coplanar with the third surface; the second chiplet is bonded to the base layer at the second surface; and a third chiplet is horizontally adjacent to the second chiplet and bonded to the base layer at the third surface.

Example 9: The IC device of example 8, wherein: the base layer comprises a first sidewall extending from the second surface to the third surface; and the composite die structure further comprises a gap between the first sidewall and a second sidewall of one of the second and third chiplets, wherein the dielectric material is in the gap.

Example 10: The IC device of any of examples 1 through 8, wherein the first interconnect layers comprise a first number of layers, the second interconnect layers comprise a second number of layers, and the first number is different from the second number.

Example 11: The IC device of any of examples 1 through 8, or example 10, wherein: the first interconnect layers comprise a plurality of first conductive layers separated by dielectric material layers, each first conductive layer comprising a thickness; the second interconnect layers comprise a plurality of second conductive layers separated by dielectric material layers, each second conductive layer comprising a thickness; a thinnest first conductive layer comprises a first thickness less than the thicknesses of other first conductive layers; and a thinnest second conductive layer comprises a second thickness less than the thicknesses of other second conductive layers, wherein the first thickness is different from the second thickness.

Example 12: The IC device of any of examples 1 through 8, or examples 10 through 11, wherein the first chiplet comprises first device layers comprising first transistors comprising a single gate, and the second chiplet comprises second device layers comprise second transistors comprising two or more gates.

Example 13: The IC device of any of examples 1 through 8, or example 12, wherein: the first chiplet comprises first device layers comprising a first feature, wherein the first feature of the first device layers comprises a first dimension; the second chiplet comprises second device layers comprising the first feature, wherein the first feature of the second device layers comprises a second dimension different from the first dimension.

Example 14: A system, comprising: a composite integrated circuit (IC) die comprising: a base layer comprising bulk silicon and a first chiplet integral with the base layer, the first chiplet comprising first interconnects in first interconnect layers; a second chiplet bonded to the base layer and horizontally adjacent to the first chiplet, the second chiplet comprising second interconnects in second interconnect layers; a first dielectric material between the first and second chiplets; and third interconnect layers extending over both the first and second interconnect layers, the third interconnect layers comprising third interconnects and a second dielectric material different from the first dielectric material, and a surface comprising conductive contacts opposite the base layer of the composite IC die, wherein the third interconnects are coupled with the first interconnects, the second interconnects, and the conductive contacts; a package substrate coupled with the conductive contacts.

Example 15: The system of example 14, wherein: the base layer further comprises: a first surface, a second surface, and a third surface, wherein the second and third surfaces are both opposite the first surface, and the second surface is non-coplanar with the third surface; the second chiplet is bonded to the base layer at the second surface; and the composite IC further comprises a third chiplet is horizontally adjacent to the second chiplet and bonded to the base layer at the third surface.

Example 16: The system of example 15, wherein: the first chiplet comprises a first thickness extending between the third interconnect layers and a lowest level of a first device layer under the first interconnect layers; and the second chiplet comprises a second thickness extending between the third interconnect layers and a lowest level of a second device layer under the second interconnect layers, wherein the second thickness is different from the first thickness.

Example 17: A method, comprising: forming a first chiplet on a base layer of a composite die structure comprising bulk silicon; forming a fill structure on the base layer in a first region adjacent to the first chiplet; forming a cavity in the first region; bonding a second chiplet to the base layer in the first region; providing a dielectric material in a gap between the first and second chiplets; and forming interconnect layers extending over both the first and second chiplets.

Example 18: The method of example 17, wherein the forming a first chiplet comprises forming a first number of first interconnect layers, and the first number is different from a second number of second interconnect layers in the second chiplet.

Example 19: The method of any of example 17 or example 18, wherein the bonding the second chiplet to the base layer comprises thermocompression bonding.

Example 20: The method of any of examples 17 through 19, further comprising providing an etch stop layer in the base layer adjacent to the second chiplet.

However, the above embodiments are not limited in this regard, and, in various implementations, the above embodiments may include the undertaking of only a subset of such features, undertaking a different order of such features, undertaking a different combination of such features, and/or undertaking additional features than those features explicitly listed. The scope of the disclosure should therefore be determined with reference to the appended claims, along with the full scope of equivalents to which such claims are entitled.

What is claimed is:

1. An integrated circuit (IC) device, comprising:
a base layer of a composite die structure comprising bulk silicon and a first chiplet integral with the base layer, the first chiplet comprising first interconnects in first interconnect layers;
a second chiplet bonded to the base layer and horizontally adjacent to the first chiplet, the second chiplet comprising second interconnects in second interconnect layers;
a dielectric material between the first and second chiplets; and
third interconnect layers extending over both the first and second interconnect layers, the third interconnect layers comprising third interconnects, and a surface comprising conductive contacts opposite the base layer of the composite die structure, wherein the third interconnects are coupled with the first interconnects, the second interconnects, and the conductive contacts.

2. The IC device of claim 1, wherein:
the dielectric material is a first dielectric material;
the first interconnect layers comprise a plurality of inter-layer dielectric (ILD) material layers;
the first chiplet comprises a device layer under the first interconnect layers; and
a layer of the ILD material layers proximate the device layer comprises a second dielectric material different from the first dielectric material.

3. The IC device of claim 2, wherein the first dielectric material comprises a first relative dielectric permittivity, and the second dielectric material comprises a second relative dielectric permittivity lower than the first relative dielectric permittivity.

4. The IC device of claim 1, wherein the dielectric material is a first dielectric material, and the third interconnect layers comprise a second dielectric material different from the first dielectric material.

5. The IC device of claim 4, wherein:
the first dielectric material comprises an inorganic material; and
the second dielectric material comprises an organic material.

6. The IC device of claim 1, further comprising a stop layer between the second chiplet and the base layer.

7. The IC device of claim 1, wherein:
the first chiplet comprises a first thickness extending between the third interconnect layers and a lowest level of a first device layer under the first interconnect layers; and
the second chiplet comprises a second thickness extending between the third interconnect layers and the base layer, wherein the second thickness is different from the first thickness.

8. The IC device of claim 1, wherein:
the base layer further comprises:
a first surface, a second surface, and a third surface, wherein the second and third surfaces are both opposite the first surface, and the second surface is non-coplanar with the third surface;
the second chiplet is bonded to the base layer at the second surface; and
a third chiplet is horizontally adjacent to the second chiplet and bonded to the base layer at the third surface.

9. The IC device of claim 8, wherein:
the base layer comprises a first sidewall extending from the second surface to the third surface; and
the composite die structure further comprises a gap between the first sidewall and a second sidewall of one of the second and third chiplets, wherein the dielectric material is in the gap.

10. The IC device of claim 1, wherein the first interconnect layers comprise a first number of layers, the second interconnect layers comprise a second number of layers, and the first number is different from the second number.

11. The IC device of claim 1, wherein:
the first interconnect layers comprise a plurality of first conductive layers separated by dielectric material layers, each first conductive layer comprising a thickness;
the second interconnect layers comprise a plurality of second conductive layers separated by dielectric material layers, each second conductive layer comprising a thickness;
a thinnest first conductive layer comprises a first thickness less than the thicknesses of other first conductive layers; and
a thinnest second conductive layer comprises a second thickness less than the thicknesses of other second conductive layers, wherein the first thickness is different from the second thickness.

12. The IC device of claim 1, wherein the first chiplet comprises first device layers comprising first transistors comprising a single gate, and the second chiplet comprises second device layers comprise second transistors comprising two or more gates.

13. The IC device of claim 1, wherein:
the first chiplet comprises first device layers comprising a first feature, wherein the first feature of the first device layers comprises a first dimension;
the second chiplet comprises second device layers comprising the first feature, wherein the first feature of the second device layers comprises a second dimension different from the first dimension.

14. A system, comprising:
a composite integrated circuit (IC) die comprising:
a base layer comprising bulk silicon and a first chiplet integral with the base layer, the first chiplet comprising first interconnects in first interconnect layers;
a second chiplet bonded to the base layer and horizontally adjacent to the first chiplet, the second chiplet comprising second interconnects in second interconnect layers;
a first dielectric material between the first and second chiplets; and
third interconnect layers extending over both the first and second interconnect layers, the third interconnect layers comprising third interconnects and a second dielectric material different from the first dielectric material, and a surface comprising conductive contacts opposite the base layer of the composite IC die, wherein the third interconnects are coupled with the first interconnects, the second interconnects, and the conductive contacts;
a package substrate coupled with the conductive contacts.

15. The system of claim 14, wherein:
the base layer further comprises:
a first surface, a second surface, and a third surface, wherein the second and third surfaces are both opposite the first surface, and the second surface is non-coplanar with the third surface;
the second chiplet is bonded to the base layer at the second surface; and
the composite IC further comprises a third chiplet is horizontally adjacent to the second chiplet and bonded to the base layer at the third surface.

16. The system of claim 15, wherein:
the first chiplet comprises a first thickness extending between the third interconnect layers and a lowest level of a first device layer under the first interconnect layers; and
the second chiplet comprises a second thickness extending between the third interconnect layers and a lowest level of a second device layer under the second interconnect layers, wherein the second thickness is different from the first thickness.

17. A method, comprising:
forming a first chiplet on a base layer of a composite die structure comprising bulk silicon;
forming a fill structure on the base layer in a first region adjacent to the first chiplet;
forming a cavity in the first region;
bonding a second chiplet to the base layer in the first region;
providing a dielectric material in a gap between the first and second chiplets; and
forming interconnect layers extending over both the first and second chiplets.

18. The method of claim 17, wherein the forming a first chiplet comprises forming a first number of first interconnect layers, and the first number is different from a second number of second interconnect layers in the second chiplet.

19. The method of claim 17, wherein the bonding the second chiplet to the base layer comprises thermocompression bonding.

20. The method of claim 17, further comprising providing an etch stop layer in the base layer adjacent to the second chiplet.
